(19) United States
(12) Patent Application Publication
(10) Pub. No.: US 2004/0164799 A1
(43) Pub. Date: Aug. 26, 2004

(54) Amplifier

(76) Inventors: Isaiah Watas Cox, London (GB); Stuart Harbron, Berkhamsted (GB)

Correspondence Address: Borealls Technical Limited, 23545 NW Skyline Blvd, North Plains, OR, 97133-9204, US

(21) Appl. No.: 10/779,068

(22) Filed: Feb. 12, 2004

(30) Foreign Application Priority Data
Feb. 12, 2003 (GB) GB0303148.1

(51) Int. Cl. H03F 13/00

(52) U.S. Cl. 330/174

(57) ABSTRACT

In general terms, the present invention is an amplifier based on a diode device in which the separation of the electrodes controls the magnitude of the current flowing through the diode. The amplifier of the present invention comprises an emitter electrode separated from a collector electrode by a distance; one or more positioning elements in contact with either or both electrodes to control the magnitude of the distance; a heater element in thermal contact with the emitter electrode; a controller element having an electrical input to be amplified in electrical contact with the positioning elements so as to control the magnitude of the distance; and an amplified output between the collector and the emitter.

### CROSS-REFERENCE TO RELATED APPLICATIONS

This application claims the benefit of United Kingdom Patent Application No. GB0303148.1, filed Feb. 12, 2003.

### BACKGROUND OF THE INVENTION

This invention relates to amplifiers.

An amplifier is a device that increases the strength of an electrical signal by drawing energy from a separate source to that of the signal. The original device used in electronic amplifiers was the triode valve, in which the cathode-anode current is varied in accordance with the low-voltage signal applied to the valve's control grid. In the more recent transistor, the emitter-collector current is controlled in much the same way by the signal applied to the transistor's base region.

Close-spaced thermionic/thermotunnel converters of the type disclosed in WO99/13562 produce electricity from a heat or similar energy source. These are gap diode devices in which one of the electrodes serves as an emitter and the other is a collector. The voltage produced by these devices is approximately dependent on the difference in work function between the emitter electrode and the collector electrode. The current generated is a function of the separation of the electrodes. The separation of the electrodes is controlled using active elements, such as piezo electric transducers.

A Gap Diode having a tubular actuating element that serves as both a housing for a pair of electrodes and as a means for controlling the separation between the electrode pair is disclosed in WO03/090245. The Gap Diode is fabricated by micromachining techniques in which the separation of the electrodes is controlled by piezo-electric, electrostrictive or magnetostrictive actuators.

The piezoelectric crystal bends in different ways at different frequencies. The crystal can be made into various shapes to achieve different vibration modes. To realize small, cost effective, and high performance products, several modes have been developed to operate over several frequency ranges. These modes allow the manufacture of products working in the low kHz range up to the GHz range for many useful products, such as ceramic resonators, ceramic bandpass filters, ceramic discriminators, ceramic traps, SAW filters, and buzzers. One mode is Thickness Longitudinal Vibration (6.3 MHz to 13.0 MHz); in this mode, the substrate thickness expands and contracts. The resonant frequency is determined by the thickness of the substrate. This mode operates from 6.3 MHz to 13.0 MHz. Use of an aeolotropic ceramic material, in which the fundamental response of the thickness longitudinal vibration mode is suppressed allowing use of the third overtone, this range can be extended to cover 12 MHz to 60 MHz.

### BRIEF SUMMARY OF THE INVENTION

In general terms, the present invention is an amplifier based on a gap diode device in which the separation of the electrodes controls the magnitude of the current flowing through the diode. The amplifier of the present invention comprises an emitter electrode separated from a collector electrode by a distance; one or more positioning elements in contact with either or both electrodes to control the magnitude of the distance; a heater element in thermal contact with the emitter electrode; a controller element having an electrical input to be amplified in electrical contact with the positioning elements so as to control the magnitude of the distance; and an amplified output between the collector and the emitter. The gain of the amplifier is set by the separation of the electrodes, the bias applied across the electrodes, and by the heat supplied to the emitter electrode. The gap diode device may be a thermionic gap diode or a tunneling gap diode.

### BRIEF DESCRIPTION OF THE SEVERAL VIEWS OF THE DRAWING

For a more complete explanation of the present invention and the technical advantages thereof, reference is now made to the following description and the accompanying drawing in which:

FIG. 1 shows a gap diode amplifier of the present invention.

FIG. 2 shows one embodiment of a circuit using the amplifier of the invention.

FIGS. 3a and 3b show examples of the output from the amplifier of the invention.

### DETAILED DESCRIPTION OF THE INVENTION

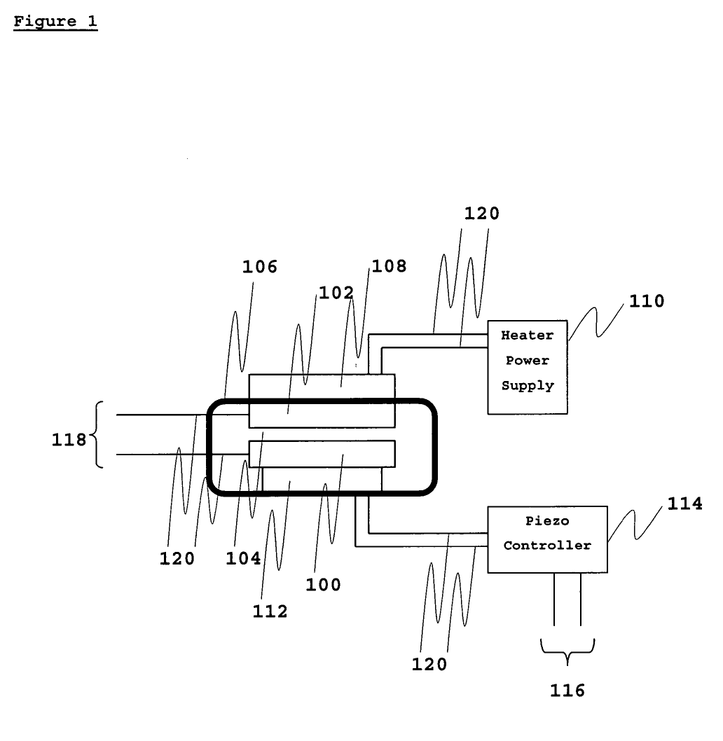

Embodiments of the present invention and their technical advantages may be better understood by referring to FIG. 1.

Referring now to FIG. 1, which shows one embodiment of the present invention, an emitter electrode 102 and a collector electrode 100 are separated by a region 104 and housed in a housing 106. Electrode 102 is in thermal contact with a heating element 108, which is connected to a heater power supply 110 via connecting wires 120. Electrode 100 is functionally connected to a positioning element 112. In a preferred embodiment the positioning element is a piezo-electric actuator. An electric field is applied to the piezo-electric actuator by a controller 114 via connecting wires 120, which causes it to expand or contract longitudinally, thereby altering the separation of the electrodes. An electrical input signal to be amplified is applied at 116 to the piezo controller. An amplified electrical output is available at 118. The gain of the amplifier is set by the separation of the electrodes, and by the heat supplied to the emitter electrode. The gap between the two electrodes is preferably in the range 0.5 to 500 nm and most preferably in the range of 4 to 20 nm, in which case electrons are able to tunnel between the emitter electrode and the collector electrode, leading to a device with much higher gain.

In operation, an oscillating signal applied at 116 to the piezo controller results in a periodic alteration of the distance separating the electrodes, 104. Oscillation of one or more electrodes in this fashion results in an amplified oscillating output from the gap diode device shown in FIG. 1.

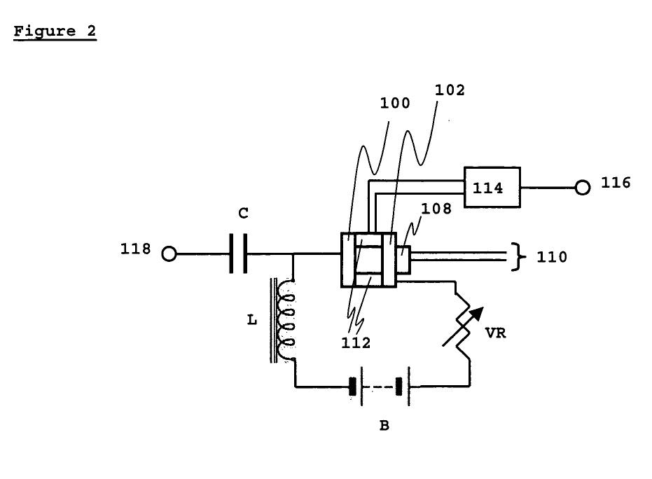

Referring now to FIG. 2, which shows a further embodiment of the present invention, a circuit containing the gap diode amplifier is shown. The gap diode shown here comprises an emitter electrode, 102, and a collector electrode, 100, and piezo-electric actuators 112 control the separation between them. For the sake of simplicity, the housing is not shown in this representation. In a preferred embodiment, piezo-electric actuator 112 is a cylinder having a cross section that is circular, oval, or polygonal, and also forms the housing, as disclosed in WO03/090245. Controller 114 applies a signal derived from input 116 to the piezo element. In an alternative embodiment, the input signal is applied directly to the piezo-electric actuator or actuators. A bias voltage is applied across the gap diode by means of a dc power source, B, and a variable resistor, R; a fixed resistor may substitute the variable resistor. The bias voltage is preferably in the range of 0.5 to 50 V. Inductor L serves to prevent the oscillating output of the gap diode feeding into the dc power source. Capacitor C serves to prevent dc current from being drawn from the dc power source by the load on output 118. Heating element 108 is powered by the heater power supply 110; the amount of heat supplied to the emitter is chosen to adjust the gain of the amplifier and the temperature of the heating element is typically set to be between ambient and 90 C. Higher temperatures may be chosen, depending on the application, for example if the device is operating in a hot environment. The operating temperature is preferably in the range of 250 to 450K. The heater power supply also includes a temperature sensor mounted on or near the heating element so that the temperature of the heating element may be regulated (not shown in FIG. 2). The work function of the emitter electrode is preferably in the range of 0.5 to 1.5 eV

In operation a signal to be amplified is applied at the input, 116. FIG. 2 shows piezo controller 114, which serves as a preamplifier, and may additionally comprise filtering elements to condition the input signal prior to its application to the piezo-electric actuator or actuators. In an alternative embodiment, the input signal is applied directly to the piezo-electric actuator or actuators. In either case, the signal causes the piezo-electric actuator or actuators to vibrate, which alters the distance between the electrodes in a manner that is directly proportional to the signal applied at the input.

In a gap diode device of the kind shown in FIGS. 1 and 2, the output current is dependent on the emission of hot electrons from the surface of the emitter, which move ballisticaly to the collector, or in the case of a tunneling gap diode, on the tunneling of electrons from the emitter to the collector. The magnitude of the current produced depends on the work function of the emitter surface, the separation of the electrodes, the operating temperature and the bias voltage.

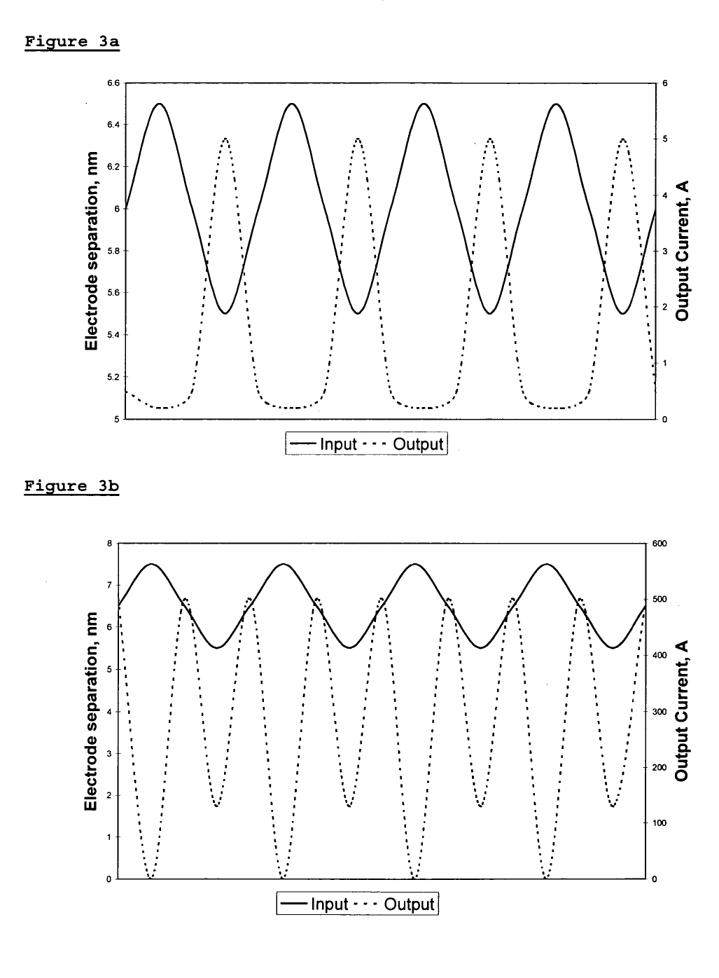

The performance of gap diodes has been described by Hishinuma et al. [Appl. Phys. Lett. (2001) 78(17), 2572-2574]. For example, at a separation of 6 nm, and at a bias voltage of 2 V at 300K, the current is about 0.5 A/cm² for a 1.2 eV surface. As this separation oscillates about 6 nm, then so does the output current; at 6.5 nm it is typically 0.2 A and at 5.5 nm it is 5 A, leading to a modulation of the signal as shown in FIG. 3a.

The cooling power has a maximum value, and in another example operating temperature and bias voltage may adjusted to set this as the DC operating point for the device. For example, at a separation of 6.5 nm, a bias voltage of 1 V at 300K, the current is about 500 A/cm² for a 1 eV work function surface. Oscillation around this value gives a concomitant oscillation in current; so at 7.5 the current is typically 130 A/cm² and at 5.5 nm it is <0.001 A/cm²—this gives a modulation of the signal as shown in FIG. 3b.

Thus by selecting the bias voltage and operating temperature appropriately, the output function of the amplifier may be varied.

While the above description contains many specificities, these should not be construed as limitations on the scope of the invention, but rather as an exemplification of one preferred embodiment thereof. Many other variations are possible. Accordingly, the scope of the invention should be determined not by the embodiments illustrated, but by the appended claims and their legal equivalents.

1. An amplifier comprising:
(a) an emitter electrode;
(b) a heater element in thermal contact with said emitter electrode;
(c) a collector electrode separated from said emitter electrode by a distance;
(d) one or more positioning elements in contact with either or both electrodes, whereby the magnitude of the distance may be adjusted;
(e) a voltage means providing a voltage bias across said electrodes;
(f) an electrical input signal to be amplified, in electrical contact with said one or more positioning elements so as to modulate the magnitude of the distance;
(g) an electrical amplified output formed between said collector and said emitter.

2. The amplifier of claim 1 in which said magnitude is between 0.5 and 500 nm.

3. The amplifier of claim 1 in which said magnitude is between 4 and 20 nm.

4. The amplifier of claim 1 in which a work function of said emitter electrode is between 0.5 and 1.5 eV.

5. The amplifier of claim 1 in which a temperature of operation is in the range of 250 to 450K.

6. The amplifier of claim 1 in which said bias voltage is between 0.5 and 50V.

7. The amplifier of claim 1 additionally comprising a controller element to which the electrical input signal is applied, and which provides an electrical output to the one or more positioning elements.

8. The amplifier of claim 7 in which said controller element comprises a pre-amplifier.

9. The amplifier of claim 7 in which said controller element comprises one or more filter elements.

10. The amplifier of claim 1 in which said one or more positioning elements comprise a piezo-electric actuator.

11. The amplifier of claim 1 in which said one or more positioning elements comprise a ring.

12. The amplifier of claim 11 in which said ring is a cylinder having a cross section selected from the group consisting of: circular, oval, and polygonal.

13. A method for amplifying an electrical signal comprising the steps of:
(a) applying said electrical signal to one or more positioning elements in contact with either or both electrodes of a gap diode, causing the distance between said electrodes to vary in accordance with said signal;
(b) forming an amplified electrical output between a collector and an emitter electrode of said gap diode.

14. The method of claim 13 additionally comprising the step of applying heat to said emitter electrode.

15. The method of claim 14 in which said step of applying heat comprises maintaining a temperature of operation in the range of 250 to 450K.

16. The method of claim 13 additionally comprising the step of applying a voltage bias between said electrodes.

17. The method of claim 16 in which said step of applying a bias voltage comprises applying a voltage bias between 0.5 and 50V.

18. The method of claim 13 in which said step of applying said electrical signal comprises applying said electrical signal to a controller element, and applying an electrical output from said controller to the one or more positioning elements.

19. The method of claim 18 in which said controller element comprises a pre-amplifier.

20. The method of claim 18 in which said controller element comprises one or more filter elements.
